(19) United States
(12) Patent Application Publication
(10) Pub. No.: US 2023/0413666 A1
(43) Pub. Date: Dec. 21, 2023

(54) OLED DEVICE AND MANUFACTURING METHOD

(71) Applicant: BOE Technology Group Co., Ltd., Beijing (CN)

(72) Inventors: Rongrong GAO, Beijing (CN); Xinghua LIU, Beijing (CN); Dongxu ZHANG, Beijing (CN)

(21) Appl. No.: 18/249,997

(22) PCT Filed: Dec. 8, 2020
(86) PCT No.: PCT/CN2020/134595

§ 371 Date: Apr. 21, 2023

(51) Int. Cl. H10K 85/60; H10K 71/16; H10K 85/40

(52) U.S. Cl. CPC H10K 85/654; H10K 71/16; H10K 85/6574; H10K 85/615; H10K 85/624; H10K 85/40; H10K 85/6576; H10K 85/657; H10K 50/16

(57) ABSTRACT

Embodiments of the present invention provide an OLED device and a manufacturing method. The OLED device comprises: an anode; a hole transport layer; a light-emitting layer; an electron transport layer comprising a first electron transport body and a second electron transport body, wherein the first electron transport body has a spiral structure, the second electron transport body has a continuous π conjugated system formed by fusing a dioxin structure and a benzoheterocyclic structure, the electron mobility of the first electron transport body is less than the electron mobility of the second electron transport body, the electron mobility of the second electron transport body is 10⁻⁵-10⁻⁸ cm²V⁻¹s⁻¹@5000 V^{1/2}/m^{1/2}, the triplet-state energy level of the first electron transport body is greater than the triplet-state energy level of the second electron transport body, and the triplet-state energy level of the first electron transport body is greater than 2.4 eV; and a cathode.

### CROSS REFERENCE TO RELATED APPLICATIONS

This application is a national phase entry under 35 U.S.C. § 371 of International Application No. PCT/CN2020/134595, filed on Dec. 8, 2020, the entire content of which is incorporated herein by reference.

### FIELD

The disclosure relates to the field of semiconductor technology, in particular to an OLED device and a manufacturing method.

### BACKGROUND

In recent years, an organic light-emitting display (OLED) has attracted more and more attention as a new type of flat panel display. Due to its characteristics of active luminescence, high luminous brightness, high resolution, wide viewing angle, fast response speed, low power consumption, and flexibility, the OLED becomes a hot mainstream display product currently in the market.

With the continuous development of the OLED technology, OLED devices have gradually developed into multi-layer structured thin film devices with a plurality of functional layers, more attention has been paid to the research on efficient organic materials and the device performance that affect OLEDs, and an OLED device with high efficiency and long service life is usually a result of an optimized collocation of various organic materials, which provides great opportunities and challenges for the design and development of functional materials of various structures and device structures.

### SUMMARY

An embodiment of the disclosure provides an OLED device, including: an anode; a hole transport layer on a side of the anode; a light-emitting layer on a side of the hole transport layer facing away from the anode; an electron transport layer on a side of the light-emitting layer facing away from the hole transport layer; where the electron transport layer includes: a first electron transport body and a second electron transport body, where the first electron transport body has a spiro structure, the second electron transport body has a continuous 7E conjugated system formed by fusing a dioxin structure and a benzoheterocyclic structure, an electron mobility of the first electron transport body is less than an electron mobility of the second electron transport body, the electron mobility of the second electron transport body is 10⁻⁵ cm²V⁻¹s⁻¹-10⁻⁸ cm²V⁻¹s⁻¹, a triplet-state energy level of the first electron transport body is greater than a triplet-state energy level of the second electron transport body, and the triplet-state energy level of the first electron transport body is greater than 2.4 eV; and a cathode on a side of the electron transport layer facing away from the light-emitting layer.

In some embodiments, the spiro structure is:

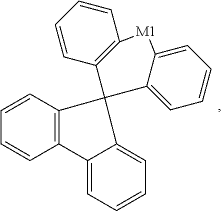

where M1 is C, O, S or N.

In some embodiments, the first electron transport body further includes an azine structure, wherein the azine structure is one of the following structures:

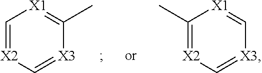

where X1 is C or N, X2 is C or N, X3 is C or N, and X1, X2, and X3 contain at least two N atoms, and a dashed line indicates a connection position with the spiro structure.

In some embodiments, a general formula of the first electron transport body is:

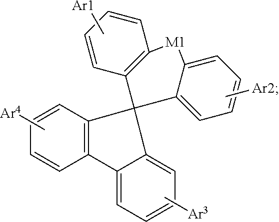

where Ar1 is an aromatic or heteroaromatic ring system composed of 5-30 aromatic rings; Ar2 is an aromatic or heteroaromatic ring system composed of 5-30 aromatic rings; Ar3 is an aromatic or heteroaromatic ring system composed of 5-30 aromatic rings; Ar4 is an aromatic or heteroaromatic ring system composed of 5-30 aromatic rings, and at least one of Ar1, Ar2, Ar3 or Ar4 includes the azine structure.

In some embodiments, at least one of Ar1, Ar2, Ar3 or Ar4 is one of the following structures:

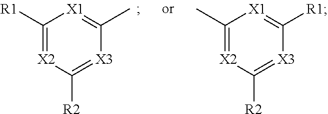

where R1 is an aromatic or heteroaromatic ring system, R2 is an aromatic or heteroaromatic ring system, and a dashed line indicates a connection position with the spiro structure.

In some embodiments, R1 or R2 contains a substituent group R3, wherein the substituent group R3 includes a first atom, and a first group and a second group which are connected with the first atom, where the first atom is nitrogen, phosphorus or boron.

In some embodiments, the substituent group R3 further includes a connecting structure, wherein the connecting structure is a single bond, B(R4), C(R4)2, Si(R4)2, C═O, C═NR4, C═C(R4)2, O, S, S═O, SO2, N(R4), P(R4) or P(═O)R4, where R4 is an aromatic or heteroaromatic ring system.

In some embodiments, the first electron transport body is one of:

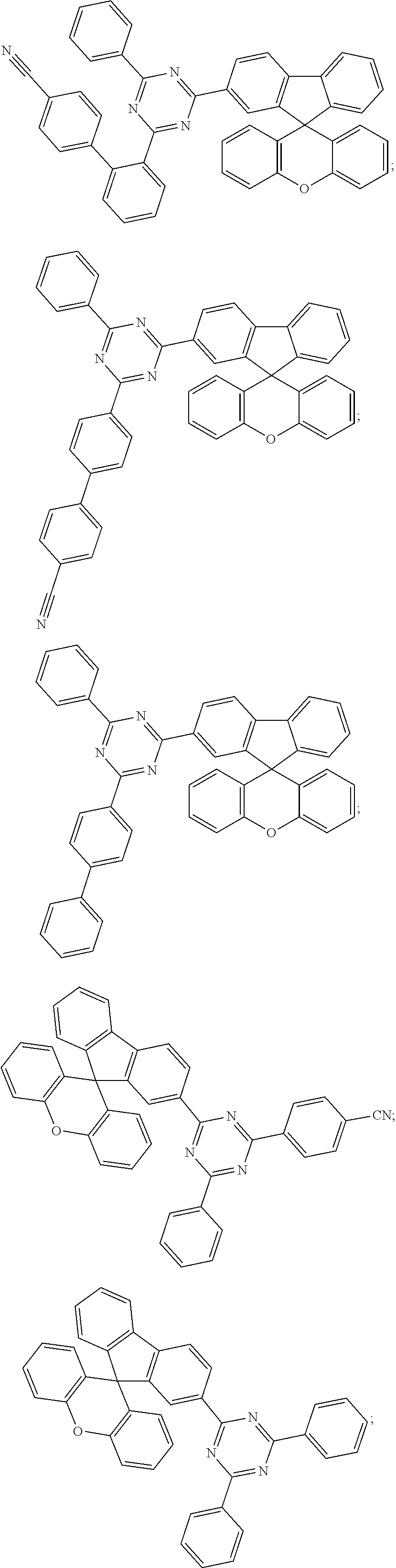

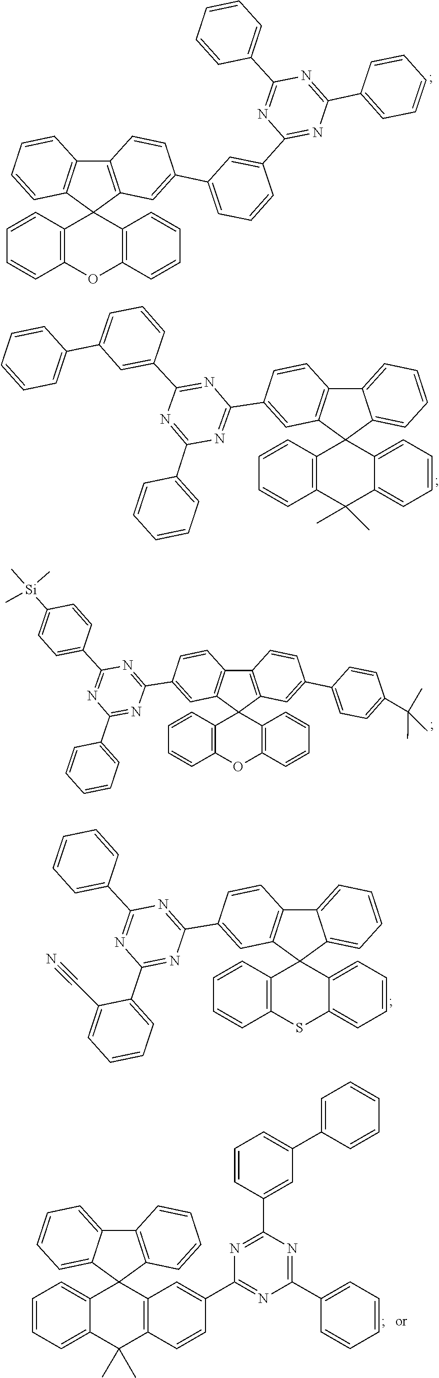

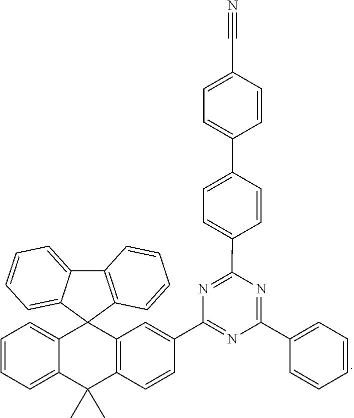 [SMILES: CC1(C)c2ccccc2C2(c3ccccc3-c3ccccc32)c2cc(-c3nc(-c4ccccc4)nc(-c4ccc(-c5ccc(C#N)cc5)cc4)n3)ccc21]

In some embodiments, the benzoheterocyclic structure includes benzofuran, benzothiophene, or indole.

In some embodiments, a general formula of the second electron transport body is:

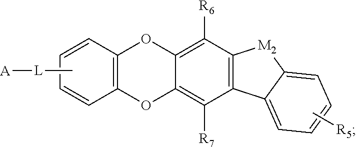

where M2 is C, O, S, or N; R₅ is hydrogen, deuterium, halogen, cyano, nitro, C1˜C40 alkyl, C2˜C40 alkenyl, C2˜C40 alkynyl, C3˜C40 cycloalkyl, C3-40 heterocycloalkyl, C6˜C60 aryl, C5-60 heteroaryl, C1˜C40 alkoxy, C6˜C60 aryloxy, C3˜C40 alkylsilyl, C6˜C60 arylsilyl, C1˜C40 alkylboryl, C6˜C60 arylboryl, C6˜C60 arylphosphinidene, C6˜C60 mono- or diarylphosphino, or C6˜C60 arylamino; R₆ is hydrogen, deuterium, halogen, cyano, nitro, C1˜C40 alkyl, C2˜C40 alkenyl, C2˜C40 alkynyl, C3˜C40 cycloalkyl, C3-40 heterocycloalkyl, C6˜C60 aryl, C5-60 heteroaryl, C1˜C40 alkoxy, C6˜C60 aryloxy, C3˜C40 alkylsilyl, C6˜C60 arylsilyl, C1˜C40 alkylboryl, C6˜C60 arylboryl, C6˜C60 arylphosphinidene, C6˜C60 mono- or diarylphosphino, or C6˜C60 arylamino; R₇ is hydrogen, deuterium, halogen, cyano, nitro, C1˜C40 alkyl, C2˜C40 alkenyl, C2˜C40 alkynyl, C3˜C40 cycloalkyl, C3-40 heterocycloalkyl, C6˜C60 aryl, C5-60 heteroaryl, C1˜C40 alkoxy, C6˜C60 aryloxy, C3˜C40 alkylsilyl, C6˜C60 arylsilyl, C1˜C40 alkylboryl, C6˜C60 arylboryl, C6˜C60 arylphosphinidene, C6˜C60 mono- or diarylphosphino, or C6˜C60 arylamino; L is a single bond, substituted C6-60 arylene, unsubstituted C6-60 arylene, or C2-60 heteroaryl containing any one or more selected from N, O, S, and Si; and A is a nitrogen-containing unsaturated ring.

In some embodiments, the second electron transport body is one of:

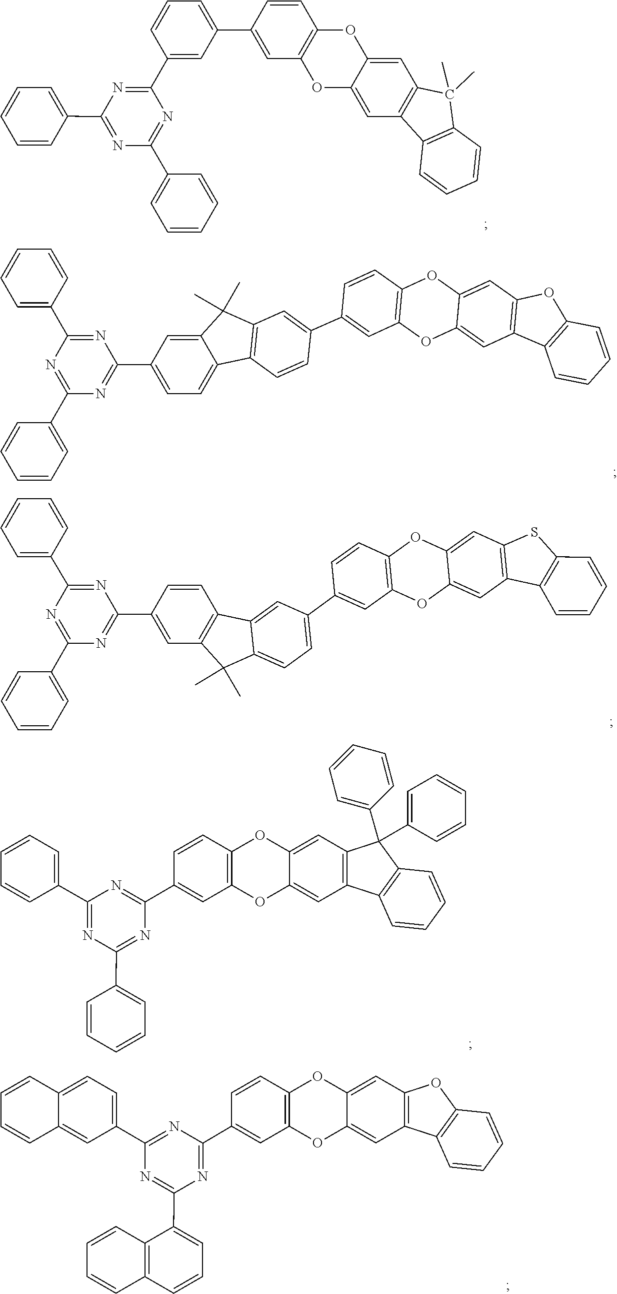

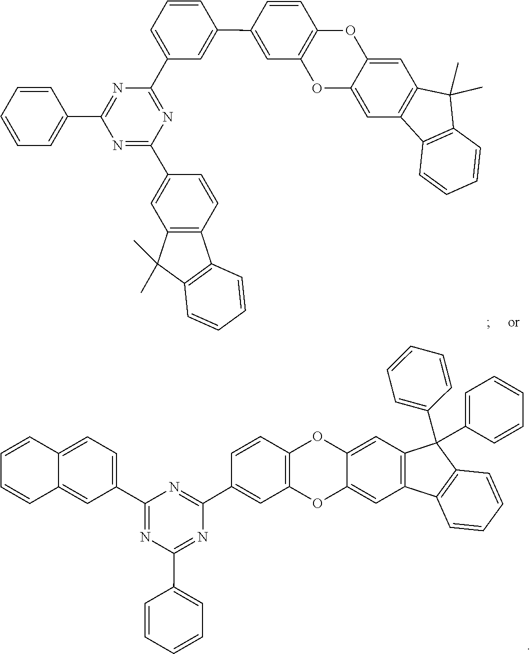 [SMILES: CC1(C)c2ccccc2-c2ccc(-c3nc(-c4ccccc4)nc(-c4cccc(-c5ccc6c(c5)Oc5cc7c(cc5O6)C(C)(C)c5ccccc5-7)c4)n3)cc21 ; c1ccc(-c2nc(-c3ccc4c(c3)Oc3cc5c(cc3O4)C(c3ccccc3)(c3ccccc3)c3ccccc3-5)nc(-c3ccc4ccccc4c3)n2)cc1]

In some embodiments, the electron mobility of the first electron transport body is 10⁻⁶ cm²V⁻¹s⁻¹-10⁻⁹ cm²V⁻¹s⁻¹.

In some embodiments, the band gap width Eg1 of the first electron transport body satisfies the following relation: 2.5 eV≤Eg1≤3.6 eV. The band gap width Eg2 of the second electron transport body satisfies the relation: 2.5 eV≤Eg2≤3.6 eV.

In some embodiments, the LUMO energy level HOMO1 of the first electron transport body and the LUMO energy level LUMO2 of the second electron transport body satisfy the following relation: 0.1 eV≤|LUMO2−LUMO1|≤0.5 eV.

In some embodiments, the HOMO energy level HOMO1, and the LUMO energy level LUMO1 of the first electron transport body satisfy the following relation: HOMO1>5.8 eV, and LUMO1>2.5 Ev. The HOMO energy level HOMO2, and the LUMO energy level LUMO2 of the second electron transport body satisfy the following relation: HOMO2>5.6 eV, and LUMO2>2.5 eV.

In some embodiments, a mass mixing ratio of the first electron transport body to the second electron transport body is 1:100 to 100:1.

In some embodiments, a difference between the evaporation temperature of the first electron transport body and the evaporation temperature of the second electron transport body is less than 30° C.

In some embodiments, an electron blocking layer is also arranged between the anode and the light-emitting layer, and a hole blocking layer is also arranged between the light-emitting layer and the electron transport layer. The triplet-state energy level of a light-emitting host in the light-emitting layer is smaller than the triplet-state energy level of the electron blocking layer, and the triplet-state energy level of the hole blocking layer is greater than the triplet-state energy level of the light-emitting host in the light-emitting layer.

In some embodiments, a hole transport layer is also arranged between the anode and the electron blocking layer. The triplet-state energy level of the second electron transport body in the electron transport layer is greater than the triplet-state energy level of the hole blocking layer; and the triplet-state energy level of the hole transport layer is greater than the triplet-state energy level of the electron blocking layer.

An embodiment of the disclosure further provides a manufacturing method for the OLED device provided by the embodiment of the disclosure, including: forming the hole transport layer on the side of the anode; forming the light-emitting layer on the side of the hole transport layer facing away from the anode; forming the electron transport layer on the side of the light-emitting layer facing away from the hole transport layer; and forming the cathode on the side of the electron transport layer facing away from the light-emitting layer. Where the forming the electron transport layer on the side of the light-emitting layer facing away from the hole transport layer includes: separately putting the first electron transport body and the second electron transport body in different evaporation sources for co-evaporation; or forming a mixture by premixing the first electron transport body with the second electron transport body, and performing evaporation by using an evaporation source.

In some embodiments, the forming the mixture by premixing the first electron transport body with the second electron transport body includes: forming the mixture by physical grinding, co-sublimation, or solvent co-dissolution.

### BRIEF DESCRIPTION OF THE DRAWINGS

FIG. 1 is a schematic structural diagram of an OLED device according to embodiments of the disclosure.

FIG. 2 is a schematic diagram of an electron transport layer according to embodiments of the disclosure.

FIG. 3 is a schematic diagram when a R2 group is substituted according to embodiments of the disclosure.

FIG. 4 is a schematic diagram when the R2 group is substituted according to embodiments of the disclosure.

FIG. 5 is a schematic diagram when the R2 group is substituted according to embodiments of the disclosure.

FIG. 6 is a schematic structural diagram of the OLED device according to embodiments of the disclosure.

FIG. 7 shows a schematic diagram of energy levels of the OLED device according to embodiments of the disclosure.

FIG. 8 is a schematic structural diagram of the OLED device according to embodiments of the disclosure.

FIG. 9 is a schematic structural diagram of the OLED device according to embodiments of the disclosure.

FIG. 10 is a schematic structural diagram of the OLED device according to embodiments of the disclosure.

FIG. 11 is a schematic diagram of manufacturing of an OLED device according to embodiments of the disclosure.

### DETAILED DESCRIPTION

In order to make the objectives, technical solutions, and advantages of the embodiments of the disclosure clearer, the technical solutions of the embodiments of the disclosure will be described clearly and completely below with reference to the accompanying drawings of the embodiments of the disclosure. Apparently, the described embodiments are some, not all, of the embodiments of the disclosure. Based on the described embodiments of the disclosure, all other embodiments obtained those of ordinary skill in the art without creative work fall within the protection scope of the disclosure.

Unless otherwise defined, technical or scientific terms used in the disclosure shall have the ordinary meaning as understood by those of ordinary skill in the art to which the disclosure belongs. “First”, “second” and similar words used in the disclosure do not represent any order, quantity, or importance, but are merely used to distinguish different components. “Include” or “comprise” and other similar words mean that an element or item preceding the word covers elements or items and their equivalents listed behind the word without excluding other elements or items. “Connection” or “connected” and other similar words may include electrical connection, direct or indirect, instead of being limited to physical or mechanical connection. “Upper”, “lower”, “left”, “right”, etc. are only used to indicate a relative position relationship, and the relative position relationship may also change accordingly when an absolute position of a described object changes.

To keep the following description of the embodiments of the disclosure clear and concise, the disclosure omits detailed descriptions of well-known functions and well-known components.

An electron transport layer (ET), as a main transport channel for carriers, has a decisive influence on the key performance of a device, such as the voltage, efficiency, and service life. Since the development of electron transport materials lags behind that of hole transport materials, the research and development, and use of the electron transport materials only focus on the molecular design of materials. Compared with traditional materials such as the 8-hydroxyquinoline aluminum salt (Alq3) and Bphen, the new materials, although their electron mobility, the material stability, etc. have been improved, still requires Liq doping. Because compounds containing metal atoms are highly reactive to oxygen, the compounds may be prone to oxidation, and the Liq materials have poor stability, and are prone to poor phenomena such as diffusion in the production process, which still has great influence on the stability of large-scale mass production of OLEDs.

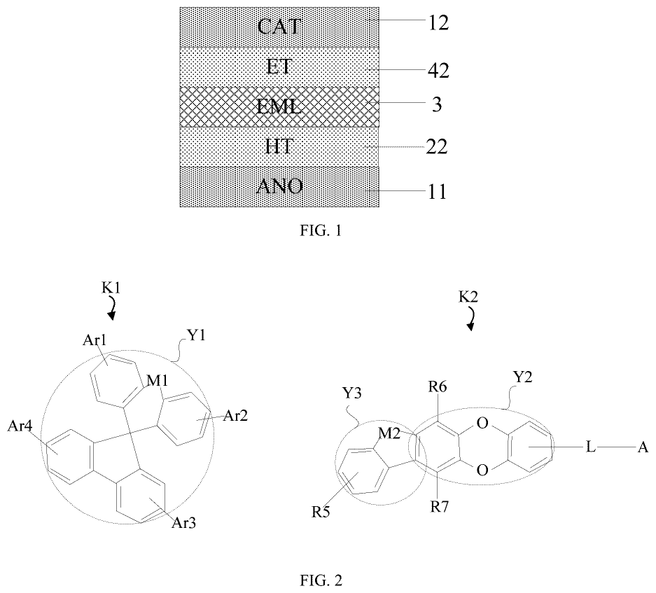

In view of this, an embodiment of the disclosure provides an OLED device, referring to FIG. 1 and FIG. 2, including:
an anode 11;
a hole transport layer 22 on a side of the anode 11;
a light-emitting layer 3 on a side of the hole transport layer 22 facing away from the anode 11;
an electron transport layer 42 on a side of the light-emitting layer 3 facing away from the hole transport layer 22, where the electron transport layer 42 includes: a first electron transport body K1 and a second electron transport body K2, where the first electron transport body K1 has a spiro structure Y1, the second electron transport body K2 has a continuous π conjugated system formed by fusing a dioxin structure Y2 and a benzoheterocyclic structure Y3, the electron mobility of the first electron transport body K1 is less than the electron mobility of the second electron transport body K2, the electron mobility of the second electron transport body K2 is 10⁻⁵ cm²V⁻¹s⁻¹-10⁻⁸ cm²V⁻¹s⁻¹, the triplet-state energy level T1 of the first electron transport body K1 is greater than the triplet-state energy level T1 of the second electron transport body K2, and the triplet-state energy level of the first electron transport body K1 is greater than 2.4 eV; and
a cathode 12 on a side of the electron transport layer 42 facing away from the light-emitting layer 3.

In the embodiment of the disclosure, provided is a new OLED device, where the electron transport layer of the OLED device includes two transport bodies, the first electron transport body K1 and the second electron transport body K2, the first electron transport body K1 has the spiro structure Y1 and has a relatively large spatial three-dimensional structure, to allow the electron transport layer to have a higher triplet-state energy level T1, and thus the spiro structure Y1 is a group with a good spatial configuration, crystallization of a material can be prevented to a certain extent, the blocking of exciton diffusion by the electron transport layer can be enhanced, and the carrier recombination and use efficiency is improved, thereby reducing the device voltage and improving the device efficiency. The second electron transport body K2 has the continuous π conjugated system formed by fusing the dioxin structure Y2 and the benzoheterocyclic structure Y3, the continuous π conjugated system has better electron mobility, thereby having a high electron mobility, easy charge dispersion and migration, good stability, and excellent charge transport ability, the electron transport efficiency of the electron transport layer can be enhanced, and a carrier (electron) transport barrier can be reduced, thereby reducing the device voltage and improving the device efficiency. Thus, this combination of the two allows the OLED device to have better performance.

It should be noted that conventional electron transport layers which mostly use an ET material doped material with LIQ

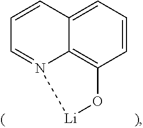

where LIQ is a metal complex which is easy to decompose when heated, which will lead to material cracking, then resulting in poor device service life. If LIQ is pre-mixed with ET material in advance, since there is an evaporation temperature difference between the ET material and LIQ, during the evaporation process, if the material temperature is too high, LIQ will crack, and if the temperature is too low, an ET material evaporation ratio is low or even not evaporated, resulting in uneven doped film. A two-component ET material provided by the embodiment of the disclosure does not have the phenomenon of uneven evaporation, and can also save a heating source and save cost.

In specific implementation, in connection with FIG. 1, the spiro structure Y1 includes:

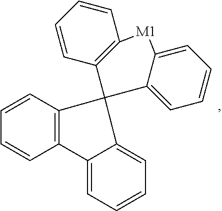

here, M1 is C, O, S or N.

It should be noted that FIG. 1 is only a schematic illustration using the spiro structure Y1 being

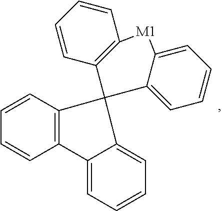

and in specific implementation, the spiro structure Y1 may also be other structures having relatively good electron transport properties and a high triplet-state energy level, which is not limited thereto in the embodiments of the disclosure.

In specific implementation, the first electron transport body K1 further includes an azine structure, wherein the azine structure is one of the following structures:

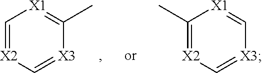

here, X1 is C or N, X2 is C or N, X3 is C or N, and there are at least two N atoms in X1, X2, and X3, and a dashed line indicates a connection position with the spiro structure. In the embodiment of the disclosure, the first electron transport body K1 further includes the azine structure which is a strong electron withdrawing group, so that the first electron transport body K1 may have a high mobility.

In specific implementation, in connection with FIG. 1, a general formula of the first electron transport body K1 is:

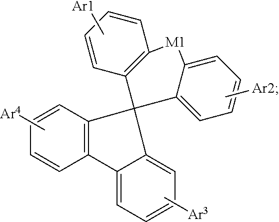

here, Ar1 is an aromatic or heteroaromatic ring system; Ar2 is an aromatic or heteroaromatic ring system; Ar3 is an aromatic or heteroaromatic ring system; and Ar4 is an aromatic or heteroaromatic ring system. Specifically, Ar1 may be an aromatic or heteroaromatic ring system composed of 5-30 aromatic rings; Ar2 may be an aromatic or heteroaromatic ring system composed of 5-30 aromatic rings; Ar3 may be an aromatic or heteroaromatic ring system composed of 5-30 aromatic rings; Ar4 may be an aromatic or heteroaromatic ring system composed of 5-30 aromatic rings, and at least one of Ar1, Ar2, Ar3 or Ar4 includes the azine structure. In particular, Ar1, Ar2, Ar3, and Ar4 may be substituted by one or more groups.

In particular, at least one of Ar1, Ar2, Ar3 or Ar4 is one of the following structures:

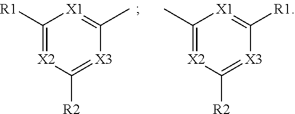

For example, in particular, among Ar1, Ar2, Ar3, and Ar4, only Ar1 may include

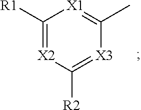

or, among Ar1, Ar2, Ar3, and Ar4, only Ar2 may include

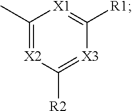

or, among Ar1, Ar2, Ar3, and Ar4, Ar1 may include

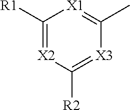

and Ar2 may include

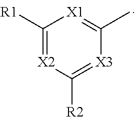

R1 is an aromatic or heteroaromatic ring system, R2 is an aromatic or heteroaromatic ring system, and a dashed line indicates a connection position with the spiro structure. In particular, R1 may be an aromatic or heteroaromatic ring system composed of 5-30 aromatic rings. In particular, R2 may be an aromatic or heteroaromatic ring system composed of 5-30 aromatic rings.

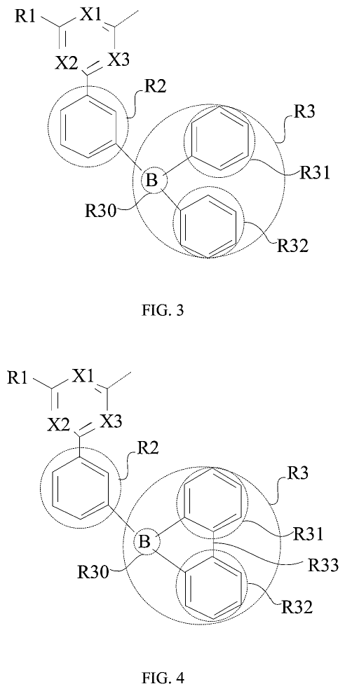

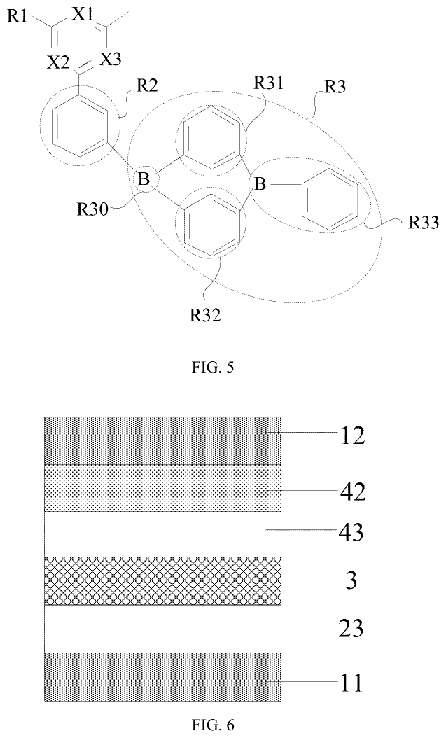

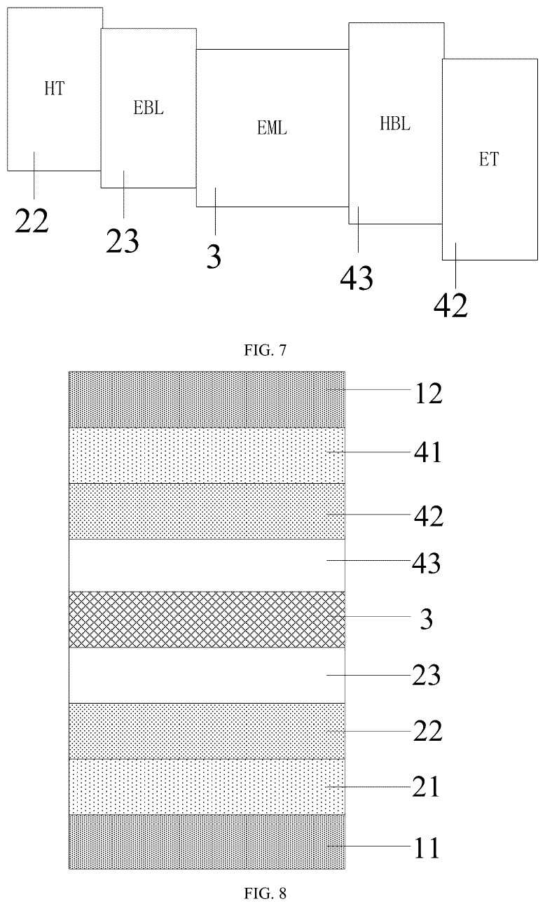

In specific implementation, R1 or R2 contains a substituent group R3. The substituent group R3 may include a first atom R30, and a first group R31 and a second group R32 which are connected to the first atom R30, where the first atom R30 is nitrogen, phosphorus or boron. Specifically, the first group R31 and the second group R32 may be independent from each other, and are not connected to each other, as shown in FIG. 3, where the first group R31 and the second group R32 each is a benzene ring. Specifically, referring to FIGS. 4 and 5, the substituent group R3 may also include a connecting structure R33, where the connecting structure R33 in particular may be a single bond, B(R4), C(R4)2, Si(R4)2, C═O, C═NR4, C═C(R4)2, O, S, S═O, SO2, N(R4), P(R4) or P(═O)R4, where R4 may be an aromatic or heteroaromatic ring system. For example, as shown in FIG. 4, the substituent group R3 may also include a connecting structure R33 which is a single bond. For another example, as shown in FIG. 5, the substituent group R3 can also include a connecting structure R33 which is B(R4), where R4 is a benzene ring.

In specific implementation, the first electron transport body K1 is one of:

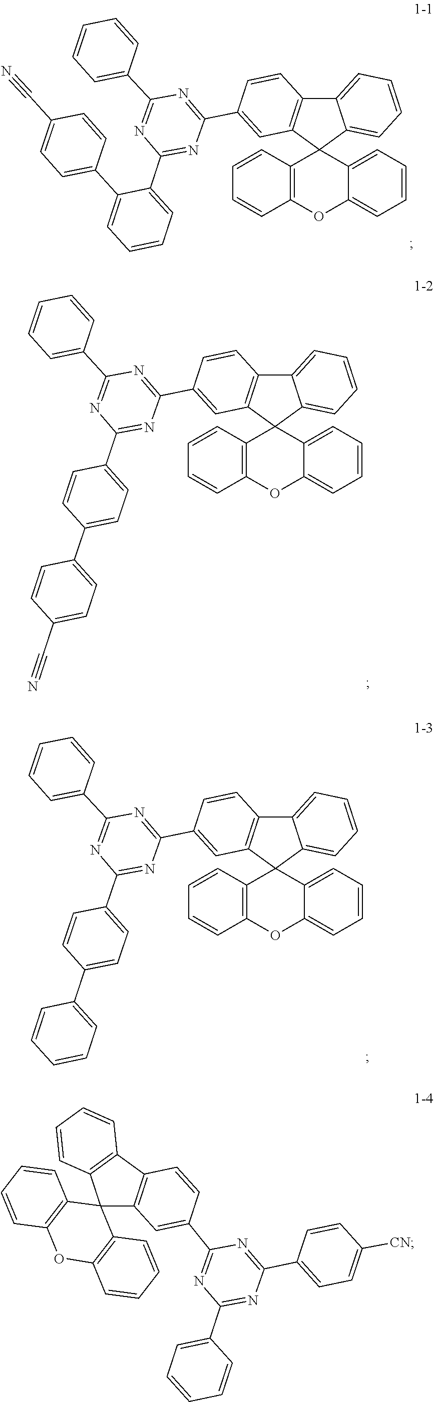 [SMILES: N#Cc1ccc(-c2ccccc2-c2nc(-c3ccccc3)nc(-c3ccc4c(c3)C3(c5ccccc5Oc5ccccc53)c3ccccc3-4)n2)cc1 ; N#Cc1ccc(-c2ccc(-c3nc(-c4ccccc4)nc(-c4ccc5c(c4)C4(c6ccccc6Oc6ccccc64)c4ccccc4-5)n3)cc2)cc1 ; c1ccc(-c2ccc(-c3nc(-c4ccccc4)nc(-c4ccc5c(c4)C4(c6ccccc6Oc6ccccc64)c4ccccc4-5)n3)cc2)cc1 ; N#Cc1ccc(-c2nc(-c3ccccc3)nc(-c3ccc4c(c3)C3(c5ccccc5Oc5ccccc53)c3ccccc3-4)n2)cc1]

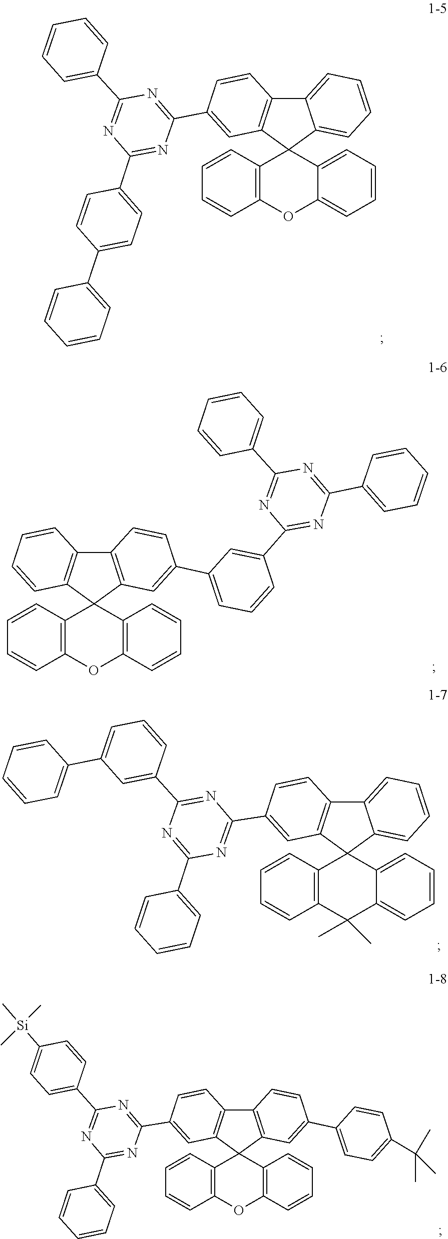 [SMILES: c1ccc(-c2ccc(-c3nc(-c4ccccc4)nc(-c4ccc5c(c4)C4(c6ccccc6Oc6ccccc64)c4ccccc4-5)n3)cc2)cc1 ; c1ccc(-c2nc(-c3ccccc3)nc(-c3cccc(-c4ccc5c(c4)C4(c6ccccc6Oc6ccccc64)c4ccccc4-5)c3)n2)cc1 ; CC1(C)c2ccccc2C2(c3ccccc3-c3ccc(-c4nc(-c5ccccc5)nc(-c5cccc(-c6ccccc6)c5)n4)cc32)c2ccccc21 ; CC(C)(C)c1ccc(-c2ccc3c(c2)C2(c4ccccc4Oc4ccccc42)c2cc(-c4nc(-c5ccccc5)nc(-c5ccc([Si](C)(C)C)cc5)n4)ccc2-3)cc1]

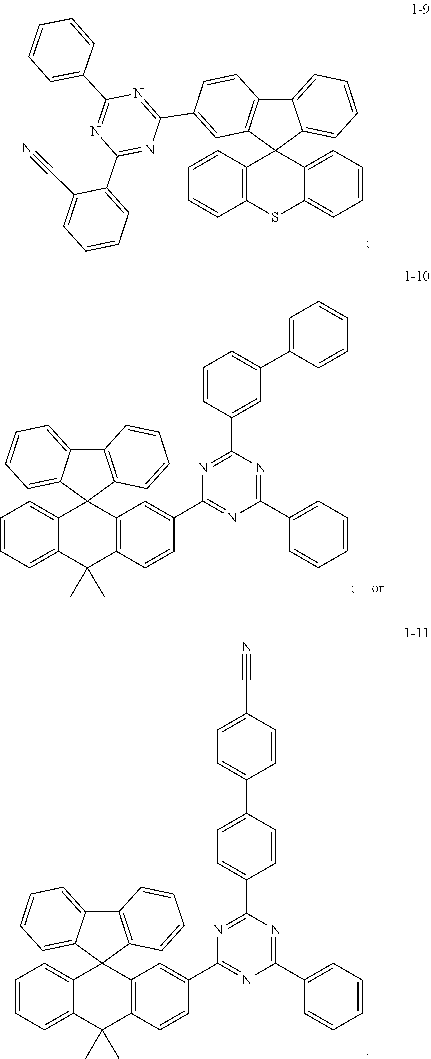 [SMILES: N#Cc1ccccc1-c1nc(-c2ccccc2)nc(-c2ccc3c(c2)C2(c4ccccc4Sc4ccccc42)c2ccccc2-3)n1 ; CC1(C)c2ccccc2C2(c3ccccc3-c3ccccc32)c2cc(-c3nc(-c4ccccc4)nc(-c4cccc(-c5ccccc5)c4)n3)ccc21 ; CC1(C)c2ccccc2C2(c3ccccc3-c3ccccc32)c2cc(-c3nc(-c4ccccc4)nc(-c4ccc(-c5ccc(C#N)cc5)cc4)n3)ccc21]

It should be noted that 1-1 to 1-11 are indexes of specific materials for different first electron transport bodies K1, so that different materials for the first electron transport body K1 are selected for manufacturing an OLED device later to facilitate description of the performance of the corresponding OLED device.

In specific implementation, the benzoheterocyclic structure Y3 may include: benzofuran, benzothiophene, or indole.

In specific implementation, a general formula of the second electron transport body K2 is:

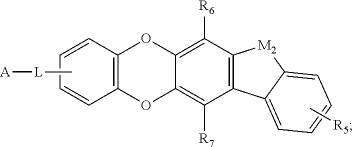

here, M2 is C, O, S or N; R₅ is hydrogen, deuterium, halogen, cyano, nitro, C1˜C40 alkyl, C2˜C40 alkenyl, C2˜C40 alkynyl, C3˜C40 cycloalkyl, C3-40 heterocycloalkyl, C6˜C60 aryl, C5-60 heteroaryl, C1˜C40 alkoxy, C6˜C60 aryloxy, C3˜C40 alkylsilyl, C6˜C60 arylsilyl, C1˜C40 alkylboryl, C6˜C60 arylboryl, C6˜C60 arylphosphinidene, C6˜C60 mono- or diarylphosphino, or C6˜C60 arylamino; R₆ is hydrogen, deuterium, halogen, cyano, nitro, C1˜C40 alkyl, C2˜C40 alkenyl, C2˜C40 alkynyl, C3˜C40 cycloalkyl, C3-40 heterocycloalkyl, C6˜C60 aryl, C5-60 heteroaryl, C1˜C40 alkoxy, C6˜C60 aryloxy, C3˜C40 alkylsilyl, C6˜C60 arylsilyl, C1˜C40 alkylboryl, C6˜C60 arylboryl, C6˜C60 arylphosphinidene, C6˜C60 mono- or diarylphosphino, or C6˜C60 arylamino; R₇ is hydrogen, deuterium, halogen, cyano, nitro, C1˜C40 alkyl, C2˜C40 alkenyl, C2˜C40 alkynyl, C3˜C40 cycloalkyl, C3-40 heterocycloalkyl, C6˜C60 aryl, C5-60 heteroaryl, C1˜C40 alkoxy, C6˜C60 aryloxy, C3˜C40 alkylsilyl, C6˜C60 arylsilyl, C1˜C40 alkylboryl, C6˜C60 arylboryl, C6˜C60 arylphosphinidene, C6˜C60 mono- or diarylphosphino, or C6˜C60 arylamine; L is a single bond, substituted C6-60 arylene, unsubstituted C6-60 arylene, or C2-60 heteroaryl containing any one or more selected from N, O, S, and Si; and A is a nitrogen-containing unsaturated ring. In particular, A is heterocyclyl having azine or cyano.

In specific implementation, the second electron transport body K2 may be one of:

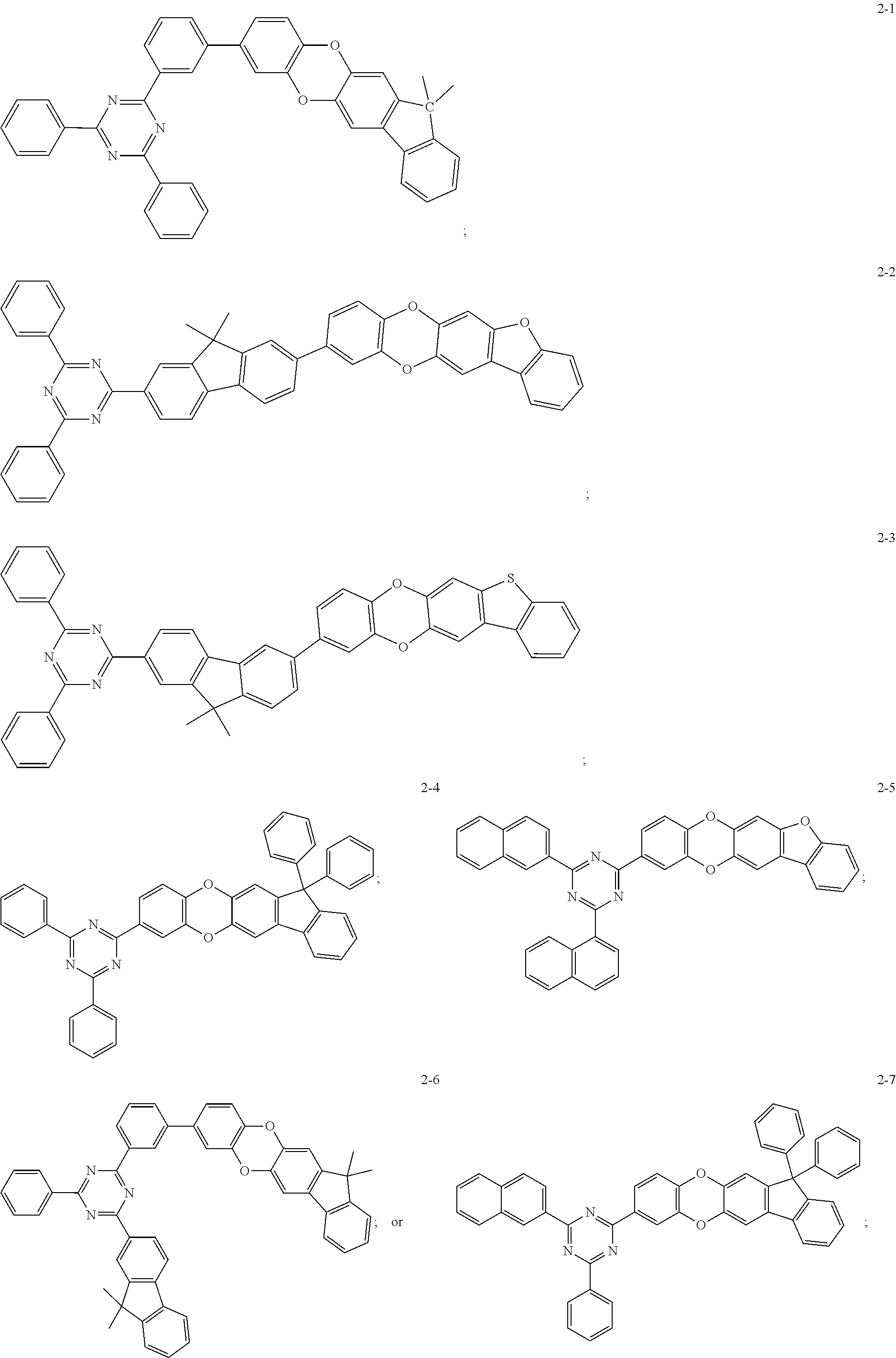

It should be noted that 2-1 to 2-7 are indexes of specific materials for different second electron transport bodies K2, so that different materials for the second electron transport body K2 are selected for manufacturing an OLED device later to facilitate description of the performance of the corresponding OLED device.

In specific implementation, the electron mobility of the first electron transport body K1 is 10⁻⁶ cm²V⁻¹s⁻¹-10⁻⁹ cm²V⁻¹s⁻¹.

In specific implementation, the band gap width Eg1 of the first electron transport body K1 satisfies the following relation:

2.5 eV≤Eg1≤3.6 eV.

The band gap width Eg2 of the second electron transport body K2 satisfies the following relation:

2.5 eV≤Eg2≤3.6 eV.

In specific implementation, the Lowest Unoccupied Molecular Orbital (LUMO) energy level LUMO1 of the first electron transport body K1 and the LUMO energy level LUMO2 of the second electron transport body satisfy the following relation: 0.1 eV≤|LUMO2−LUMO1|≤0.5 eV. In the embodiment of the disclosure, the relation 0.1 eV≤|LUMO2−LUMO1|≤0.5 eV may allow to form energy level steps during electron transport, facilitating fast electron transport.

In specific implementation, the Highest Occupied Molecular Orbital (HOMO) energy level HOMO1, and the LUMO energy level LUMO1 of the first electron transport body K1 satisfy the following relation: HOMO1>5.8 eV, and LUMO1>2.5 eV; and the HOMO energy level HOMO2, and the LUMO energy level LUMO2 of the second electron transport body satisfy the following relation: HOMO2>5.6 eV, and LUMO2>2.5 eV.

In specific implementation, a mass mixing ratio of the first electron transport body K1 to the second electron transport body K2 is 1:100 to 100:1.

In specific implementation, a difference between the evaporation temperature of the first electron transport body K1 and the evaporation temperature of the second electron transport body K2 is less than 30° C. In the embodiment of the disclosure, the difference between the evaporation temperature of the first electron transport body K1 and the evaporation temperature of the second electron transport body K2 is less than 30° C., which can avoid the situation that if the evaporation temperature difference is too large, a material having a low thermal decomposition temperature is decomposed, or a material is not evaporated in a predetermined ratio, resulting in non-uniform film, thus leading to degradation of OLED device performance. In specific implementation, evaporation may be performed at an evaporation temperature of one having a higher evaporation temperature.

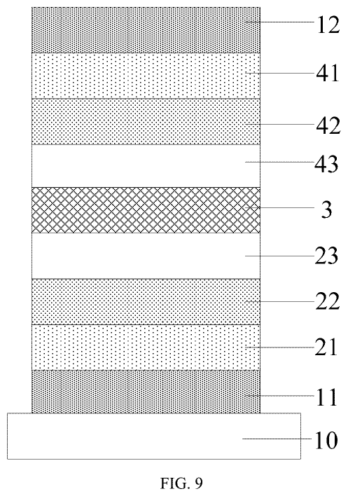

In specific implementation, referring to FIGS. 6 and 7, an electron blocking layer 23 (EBL) is arranged between the anode 11 (ANO) and the light-emitting layer 3 (EML), and a hole blocking layer 43 (HBL) is arranged between the light-emitting layer 3 (EML) and the electron transport layer 42 (ET); the triplet-state energy level of a light-emitting host in the light-emitting layer 3 (EML) is smaller than the triplet-state energy level of the electron blocking layer 23 (EBL), i.e., T1 (Host)<T1 (EBL), and the triplet-state energy level of the hole blocking layer 43 (HBL) is greater than the triplet-state energy level of the light-emitting host in the light-emitting layer 3 (EML), i.e., T1 (HBL)>T1 (Host), so as to facilitate confinement of excitons in the light-emitting layer 3 and improve the luminous efficiency. In particular, the light-emitting layer 3 (EML) may include a light-emitting host, and a light-emitting dopant.

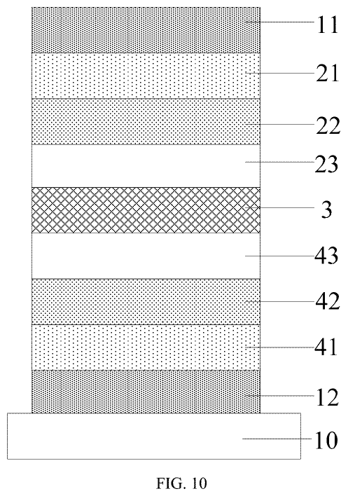

In specific implementation, referring to FIGS. 7 and 8, a hole transport layer 22 (HT) is arranged between the anode 11 (ANO) and the electron blocking layer 23 (EBL); the triplet-state energy level of the second electron transport body K2 in the electron transport layer 42 (ET) is greater than the triplet-state energy level of the hole blocking layer 43 (HBL), i.e. T1 (K2)>T1 (HBL), which prevents electron quenching caused by holes passing through the hole blocking layer 43 because the hole blocking layer 43 is too thin, and the electron transport layer 42 can simultaneously block holes; and the triplet-state energy level of the hole transport layer 22 (HT) is greater than the triplet-state energy level of the electron blocking layer 23 (EBL), i.e. T1 (HT)>T1 (EBL), which prevents electron quenching caused by electrons passing through the electron blocking layer 23 because the electron blocking layer 23 is too thin, and the electron blocking layer 23 can simultaneously block electrons.

In specific implementation, in connection with FIG. 8, the OLED device further includes a hole injection layer 21 between the anode 11 and the hole transport layer 22, and an electron injection layer 41 between the cathode 12 and the electron transport layer 42.

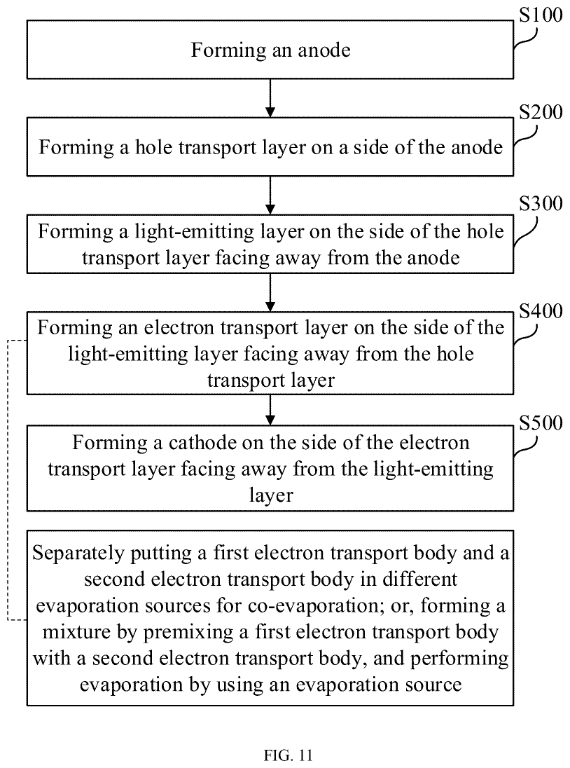

In specific implementation, the OLED device provided by the embodiment of the disclosure may be of a conventional structure, for example, as shown in FIG. 9, the OLED device includes a base substrate 10, and an anode 11, a hole injection layer 21, a hole transport layer 22, an electron blocking layer 23, a light-emitting layer 3, a hole blocking layer 43, an electron transport layer 42, an electron injection layer 41, and a cathode 12 which are sequentially disposed on a side of the base substrate 10. Or, the OLED device provided by the embodiment of the disclosure may also be of an inverted structure, for example, as shown in FIG. 10, the OLED device includes a base substrate 10, and a cathode 12, an electron injection layer 41, an electron transport layer 42, a hole blocking layer 43, a light-emitting layer 3, an electron blocking layer 23, a hole transport layer 22, a hole injection layer 21, and an anode 11 which are sequentially located on one side of the base substrate 10.

Specifically, a material of the hole injection layer 21 can be an inorganic oxide, for example, molybdenum oxide, titanium oxide, vanadium oxide, rhenium oxide, ruthenium oxide, chromium oxide, zirconium oxide, hafnium oxide, tantalum oxide, silver oxide, tungsten oxide, or manganese oxide. The material of the hole injection layer 21 may be a hole transport material doped with a p-dopant of strong electron withdrawing system, such as hexacyanohexaazatriphenylene, 2,3,5,6-tetrafluoro-7,7,8,8-tetracyano-p-quinodimethane (F4TCNQ), 1,2,3-tris[(cyano)(4-cyano-2,3,5,6-tetrafluorophenyl)methylene]cyclopropane, and the like.

Specifically, a material of the hole transport layer 22 may be an arylamine or carbazole material having hole transport properties, such as 4,4′-bis[N-(1-naphthyl)-N-phenylamino]biphenyl (NPB), N,N′-bis(3-methylphenyl)-N,N′-diphenyl-[1,1′-biphenyl]-4,4′-diamine (TPD), 4-phenyl-4′-(9-phenylfluoren-9-yl)triphenylamine (BAFLP), 4,4′-bis[N-(9,9-dimethylfluoren-2-yl)-N-phenylamino]biphenyl (DFLDPBi), 4,4′-di(9-carbazolyl)biphenyl (CBP), 9-phenyl-3-[4-(10-phenyl-9-anthryl)phenyl]-9H-carbazole (PCzPA), and the like.

Specifically, a material of the electron blocking layer 23 may be an arylamine or carbazole material having hole transport properties, such as 4,4′-bis[N-(1-naphthyl)-N-phenylamino]biphenyl (NPB), N,N′-bis(3-methylphenyl)-N,N′-diphenyl-[1,1′-biphenyl]-4,4′-diamine (TPD), 4-phenyl-4′-(9-phenylfluoren-9-yl)triphenylamine (BAFLP), 4,4′-bis[N-(9,9 dimethylfluoren-2-yl)-N-phenylamino]biphenyl (DFLDPBi), 4,4′-di(9-carbazolyl)biphenyl (CBP), 9-phenyl-3-[4-(10-phenyl-9-anthryl)phenyl]-9H-carbazole (PCzPA), and the like.

In particular, a material of the light-emitting layer 3 may be

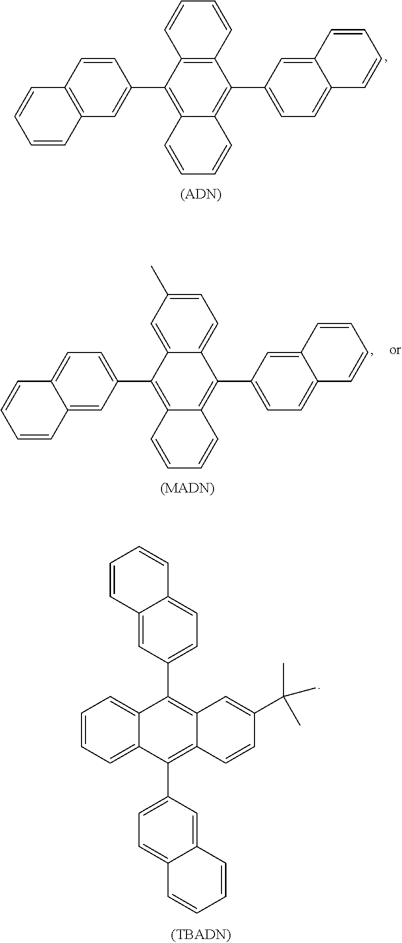

Specifically, a material of the hole blocking layer 43 can be an aromatic heterocyclic compound such as an imidazole derivative such as a benzimidazole derivative, an imidazopyridine derivative, and a benzimidazophenanthridine derivative; an azine derivative such as a pyrimidine derivative and a triazine derivative; a nitrogen-containing compound of a six-membered ring structure, such as a quinoline derivative, an isoquinoline derivative, and a phenanthroline derivative (also including a compound having a phosphine oxide-based substituent on a heterocyclic ring) and the like. 2-(4-biphenyl)-5-(4-tert-butylphenyl)-1,3,4-oxadiazole (PBD), 1,3-bis[5-(p-tert-butylphenyl)-1,3,4-oxadiazol-2-yl]benzene (OXD-7), 3-(4-tert-butylphenyl)-4-phenyl-5-(4-biphenyl)-1,2,4-triazole (TAZ), 3-(4-tert-butylphenyl)-4-(4-ethylphenyl)-5-(4-biphenyl)-1,2,4-triazole (p-EtTAZ), bathophenanthroline (BPhen), bathocuproine (BCP), 4,4′-bis(5-methylbenzoxazol-2-yl)stilbene (BzOs), and the like.

Specifically, a material of the electron injection layer 41 can be an alkali metal or a metal, such as LiF, Yb, Mg, Ca, a compound thereof, or the like.

In particular, manufacture of the OLED device in the embodiment of the disclosure can be carried out by using the following materials.

A specific structure for the OLED device is: anode (ITO)/HT:HIL 10 nm (2%)/HTL 100 nm/EBL 10 nm/Host:Dopant 20 nm (5%)/HBL 5 nm/ETL1:ETL2 30 nm (1:1)/Yb 1 nm/Mg:Ag (2:8) 80 nm, and compounds used for the functional layers may be as follows.

The material of the hole injection layer 21 (HIL) is:

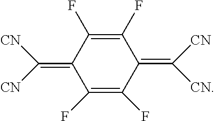

The material of the hole transport layer 22 (HT) is:

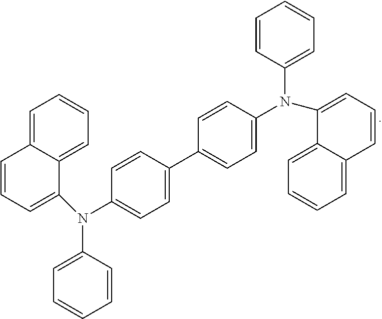 [SMILES: c1ccc(N(c2ccc(-c3ccc(N(c4ccccc4)c4cccc5ccccc45)cc3)cc2)c2cccc3ccccc23)cc1]

The material of the electron blocking layer 23 (EBL) is:

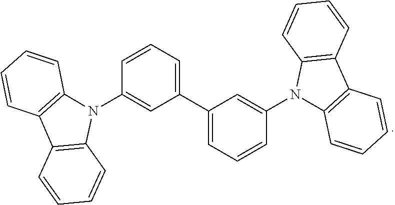 [SMILES: c1cc(-c2cccc(-n3c4ccccc4c4ccccc43)c2)cc(-n2c3ccccc3c3ccccc32)c1]

A material of the light-emitting host is:

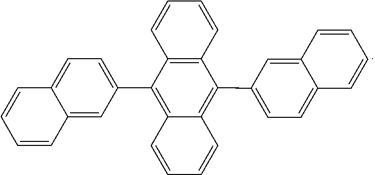 [SMILES: c1ccc2cc(-c3c4ccccc4c(-c4ccc5ccccc5c4)c4ccccc34)ccc2c1]

A material of the light-emitting dopant is:

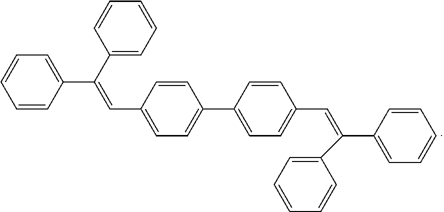 [SMILES: C(=C(c1ccccc1)c1ccccc1)c1ccc(-c2ccc(C=C(c3ccccc3)c3ccccc3)cc2)cc1]

The material of the hole blocking layer 43 (HBL) is:

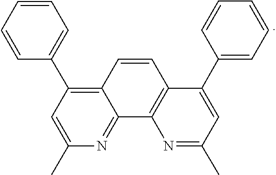 [SMILES: Cc1cc(-c2ccccc2)c2ccc3c(-c4ccccc4)cc(C)nc3c2n1]

The material of the electron transport layer 42 may be a material provided by the embodiment of the disclosure.

The efficiency and service life of the OLED device are improved to different degrees based on the energy level matching and the material combination of the embodiments of the disclosure, and the service life and efficiency will be significantly improved if the two electron transport bodies mentioned above are used simultaneously, as shown in the following table:

| | | | | Service life |
|---|---|---|---|---|
| | | | | (LT95@1000 |
| Material combination | | Voltage | Efficiency | nit) |
| Comparison | ETL-1:LIQ | 100% | 100% | 100% |
| example 1 | | | | |
| Comparison | 1-1:LIQ | 98% | 105% | 108% |
| example 2 | | | | |
| Comparison | 2-1:LIQ | 99% | 108% | 110% |
| example 3 | | | | |
| Embodiment 1 | 1-1:2-1 | 97% | 117% | 131% |
| Embodiment 2 | 1-1:2-2 | 94% | 112% | 129% |
| Embodiment 3 | 1-1:2-4 | 96% | 120% | 134% |
| Embodiment 4 | 1-2:2-1 | 94% | 118% | 123% |
| Embodiment 5 | 1-2:2-2 | 99% | 115% | 126% |
| Embodiment 6 | 1-2:2-4 | 97% | 109% | 130% |

In Comparison example 1, a device is manufactured by using two conventional electron transport materials. One material is

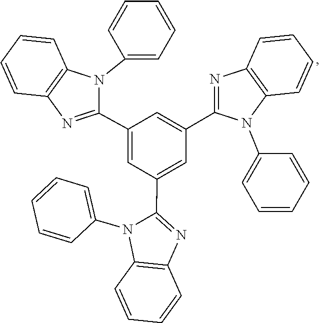 [SMILES: c1ccc(-n2c(-c3cc(-c4nc5ccccc5n4-c4ccccc4)cc(-c4nc5ccccc5n4-c4ccccc4)c3)nc3ccccc32)cc1]

and the other material is LIQ; in Comparison example 2, an OLED device is manufactured by using one material being the first electron transport body with the index of 1-1 provided by the embodiment of the disclosure, and the other material being conventional LIQ; in Comparison example 3, an OLED device is manufactured by using one material being the second electron transport body with index of 2-1 provided by the embodiment of the disclosure, and the other material being conventional LIQ; in Embodiment 1, one material is the first electron transport body with index of 1-1 provided by the embodiment of the disclosure, and the other material is the second electron transport body with index of 2-1 provided by the embodiment of the disclosure; in Embodiment 2, one material is the first electron transport body with index of 1-1 provided by the embodiment of the disclosure, and the other material is the second electron transport body with index of 2-2 provided by the embodiment of the disclosure; in Embodiment 3, one material is the first electron transport body with index of 1-1 provided by the embodiment of the disclosure, and the other material is the second electron transport body with index of 2-4 provided by the embodiment of the disclosure; in Embodiment 4, one material is the first electron transport body with index of 1-2 provided by the embodiment of the disclosure, and the other material is the second electron transport body with index of 2-1 provided by the embodiment of the disclosure; in Embodiment 5, one material is the first electron transport body with index of 1-2 provided by the embodiment of the disclosure, and the other material is the second electron transport body with index of 2-2 provided by the embodiment of the disclosure; and in Embodiment 6, one material is the first electron transport body with index of 1-2 provided by the embodiment of the disclosure, and the other material is the second electron transport body with index of 2-4 provided by the embodiment of the disclosure.

Based on the same inventive concept, an embodiment of the disclosure also provides a manufacturing method for any one of the OLED devices provided by the embodiment of the disclosure, referring to FIG. 11, including:
S100, forming an anode;
S200, forming a hole transport layer on a side of the anode;
S300, forming a light-emitting layer on the side of the hole transport layer facing away from the anode;
S400, forming an electron transport layer on the side of the light-emitting layer facing away from the hole transport layer; and
S500, forming a cathode on the side of the electron transport layer facing away from the light-emitting layer.

Here, forming the electron transport layer on the side of the light-emitting layer facing away from the hole transport layer in S400, includes:
separately putting a first electron transport body and a second electron transport body in different evaporation sources for co-evaporation; or, forming a mixture by premixing a first electron transport body with a second electron transport body, and
performing evaporation by using an evaporation source.

In specific implementation, forming a mixture by premixing a first electron transport body with a second electron transport body includes forming the mixture by physical grinding, co-sublimation, or solvent co-dissolution.

In the embodiment of the disclosure, provided is a new OLED device, where the electron transport layer of the OLED device includes two materials, the first electron transport body K1 and the second electron transport body K2. The first electron transport body K1 has the spiro structure Y1, so that the electron transport layer can have a higher triplet-state energy level T1, and the spiro structure Y1 is a group with a good spatial configuration, crystallization of a material can be inhibited to a certain extent, the blocking of exciton diffusion by the electron transport layer can be enhanced, and the carrier recombination and use efficiency is improved, thereby reducing the device voltage and improving the device efficiency; the second electron transport body K2 has the continuous π conjugated system formed by fusing the dioxin structure Y2 and the benzoheterocyclic structure Y3, the continuous π conjugated system brings better electron mobility, thereby having a high electron mobility, easy charge dispersion and migration, good stability, and excellent charge transport ability, the electron transport efficiency of the electron transport layer can be enhanced, and a carrier (electron) transport barrier can be reduced, thereby reducing the device voltage and improving the device efficiency. Thus, a combination of the two can make the OLED device have better performance.

Although the preferred embodiments of the disclosure have been described, those skilled in the art may make additional changes and modifications to these embodiments once knowing the basic inventive concept. Therefore, the appended claims are intended to be explained as including the preferred embodiments and all changes and modifications falling within the scope of the disclosure.

Obviously, those skilled in the art can make various changes and modifications to the embodiments of the disclosure without departing from the spirit and scope of the disclosure. Thus, if these changes and modifications of the embodiments of the disclosure fall within the scope of the claims of the disclosure and their equivalents, the disclosure is also intended to include these changes and modifications.

1. An OLED device, comprising:
an anode;
a hole transport layer on a side of the anode;
a light-emitting layer on a side of the hole transport layer facing away from the anode;
an electron transport layer on a side of the light-emitting layer facing away from the hole transport layer; wherein the electron transport layer includes: a first electron transport body and a second electron transport body, wherein the first electron transport body has a spiro structure, the second electron transport body has a continuous π conjugated system formed by fusing a dioxin structure and a benzoheterocyclic structure, an electron mobility of the first electron transport body is less than an electron mobility of the second electron transport body, the electron mobility of the second electron transport body is 10⁻⁵ cm²V⁻¹s⁻¹-10⁻⁸ cm²V⁻¹s⁻¹, a triplet-state energy level of the first electron transport body is greater than a triplet-state energy level of the second electron transport body, and the triplet-state energy level of the first electron transport body is greater than 2.4 eV; and
a cathode on a side of the electron transport layer facing away from the light-emitting layer.

2. The OLED device according to claim 1, wherein the spiro structure is: 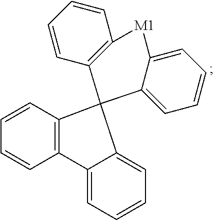
wherein M1 is C, O, S or N.

3. The OLED device according to claim 2, wherein the first electron transport body further comprises an azine structure, wherein the azine structure is one of following structures: 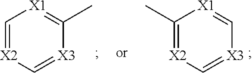
wherein X1 is C or N, X2 is C or N, X3 is C or N, and X1, X2, and X3 contain at least two N atoms, and a dashed line indicates a connection position with the spiro structure.

4. The OLED device according to claim 3, wherein a general formula of the first electron transport body is: 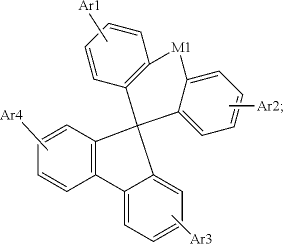
wherein
Ar1 is an aromatic or heteroaromatic ring system composed of 5-30 aromatic rings;
Ar2 is an aromatic or heteroaromatic ring system composed of 5-30 aromatic rings;
Ar3 is an aromatic or heteroaromatic ring system composed of 5-30 aromatic rings;
Ar4 is an aromatic or heteroaromatic ring system composed of 5-30 aromatic rings; and
at least one of Ar1, Ar2, Ar3 or Ar4 includes the azine structure.

5. The OLED device according to claim 4, wherein at least one of Ar1, Ar2, Ar3 or Ar4 is one of following structures: 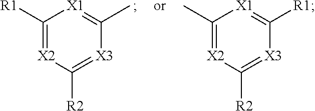
wherein
R1 is an aromatic or heteroaromatic ring system;
R2 is an aromatic or heteroaromatic ring system; and
a dashed line indicates a connection position with the spiro structure.

6. The OLED device according to claim 5, wherein R1 or R2 contains a substituent group R3, wherein the substituent group R3 comprises a first atom, and a first group and a second group which are connected with the first atom, wherein the first atom is nitrogen, phosphorus or boron.

7. The OLED device according to claim 6, wherein the substituent group R3 further comprises a connecting structure, wherein the connecting structure is a single bond, B(R4), C(R4)2, Si(R4)2, C═O, C═NR4, C═C(R4)2, O, S, S═O, SO2, N(R4), P(R4) or P(═O)R4;
wherein R4 is an aromatic or heteroaromatic ring system.

8. The OLED device according to claim 1, wherein the first electron transport body is one of:

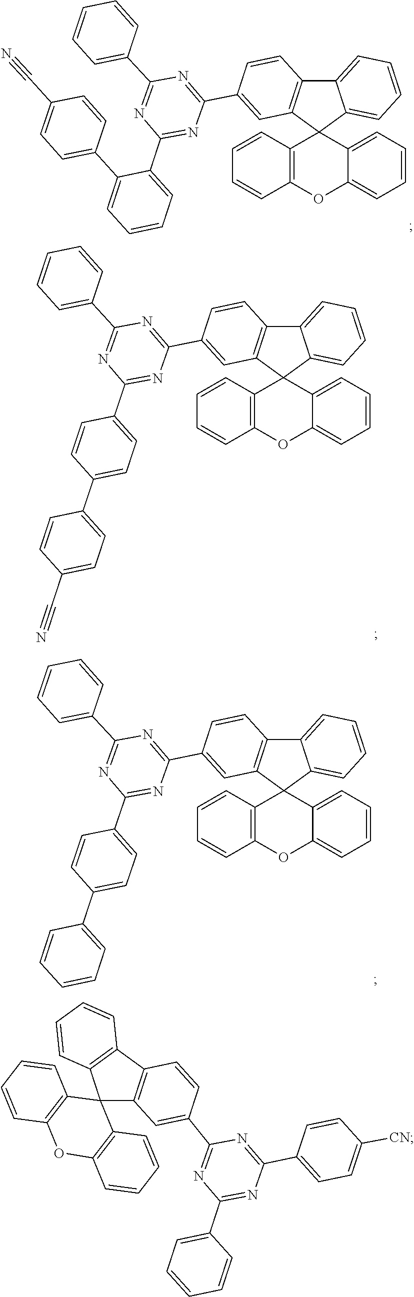

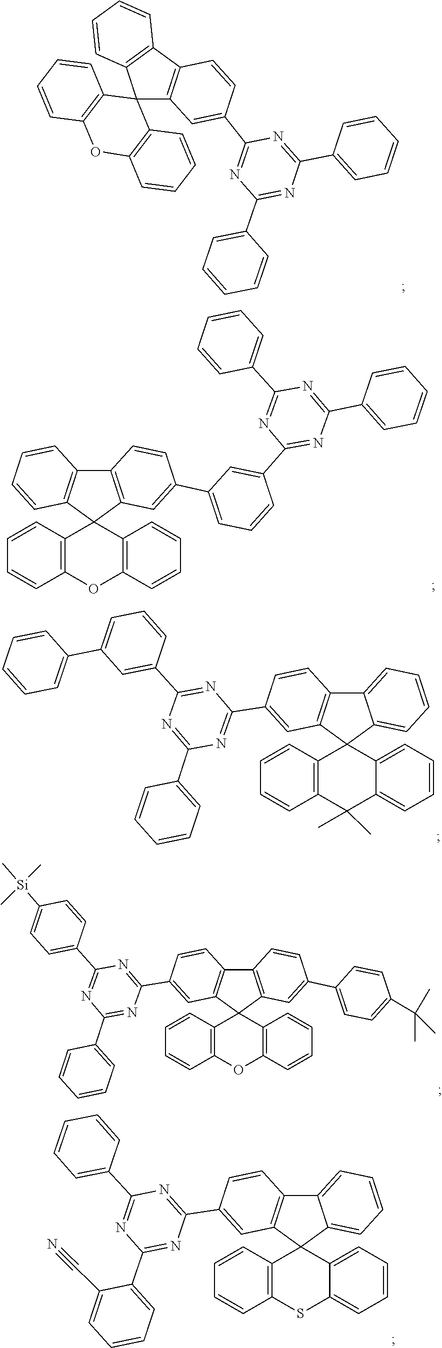

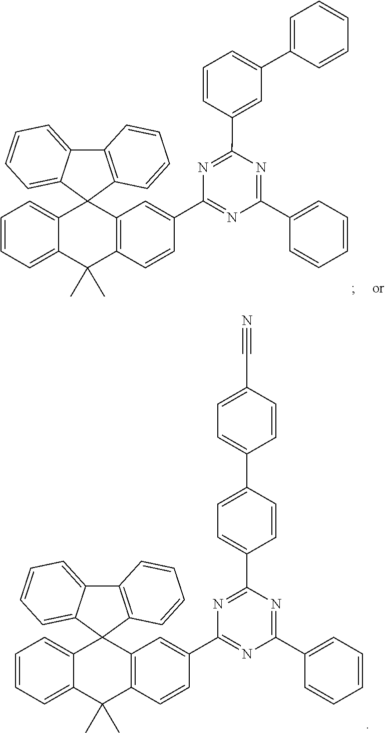 [SMILES: CC1(C)c2ccccc2C2(c3ccccc3-c3ccccc32)c2cc(-c3nc(-c4ccccc4)nc(-c4cccc(-c5ccccc5)c4)n3)ccc21 ; CC1(C)c2ccccc2C2(c3ccccc3-c3ccccc32)c2cc(-c3nc(-c4ccccc4)nc(-c4ccc(-c5ccc(C#N)cc5)cc4)n3)ccc21]

9. The OLED device according to claim 1, wherein the benzoheterocyclic structure comprises benzofuran, benzothiophene, or indole.

10. The OLED device according to claim 9, wherein a general formula of the second electron transport body is: 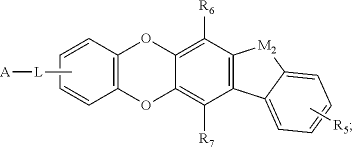
wherein
M₂ is C, O, S, or N;
R₅ is hydrogen, deuterium, halogen, cyano, nitro, C1˜C40 alkyl, C2˜C40 alkenyl, C2˜C40 alkynyl, C3˜C40 cycloalkyl, C3-40 heterocycloalkyl, C6˜C60 aryl, C5-60 heteroaryl, C1˜C40 alkoxy, C6˜C60 aryloxy, C3˜C40 alkylsilyl, C6˜C60 arylsilyl, C1˜C40 alkylboryl, C6˜C60 arylboryl, C6˜C60 arylphosphinidene, C6˜C60 mono- or diarylphosphino, or C6˜C60 arylamino;
R₆ is hydrogen, deuterium, halogen, cyano, nitro, C1˜C40 alkyl, C2˜C40 alkenyl, C2˜C40 alkynyl, C3˜C40 cycloalkyl, C3-40 heterocycloalkyl, C6˜C60 aryl, C5-60 heteroaryl, C1˜C40 alkoxy, C6˜C60 aryloxy, C3˜C40 alkylsilyl, C6˜C60 arylsilyl, C1˜C40 alkylboryl, C6˜C60 arylboryl, C6˜C60 arylphosphinidene, C6˜C60 mono- or diarylphosphino, or C6˜C60 arylamino;
R₇ is hydrogen, deuterium, halogen, cyano, nitro, C1˜C40 alkyl, C2˜C40 alkenyl, C2˜C40 alkynyl, C3˜C40 cycloalkyl, C3-40 heterocycloalkyl, C6˜C60 aryl, C5-60 heteroaryl, C1˜C40 alkoxy, C6˜C60 aryloxy, C3˜C40 alkylsilyl, C6˜C60 arylsilyl, C1˜C40 alkylboryl, C6˜C60 arylboryl, C6˜C60 arylphosphinidene, C6˜C60 mono- or diarylphosphino, or C6˜C60 arylamino;
L is a single bond, substituted C6-60 arylene, unsubstituted C6-60 arylene, or C2-60 heteroaryl containing any one or more selected from N, O, S, and Si; and
A is a nitrogen-containing unsaturated ring.

11. The OLED device according to claim 1, wherein the second electron transport body is one of:

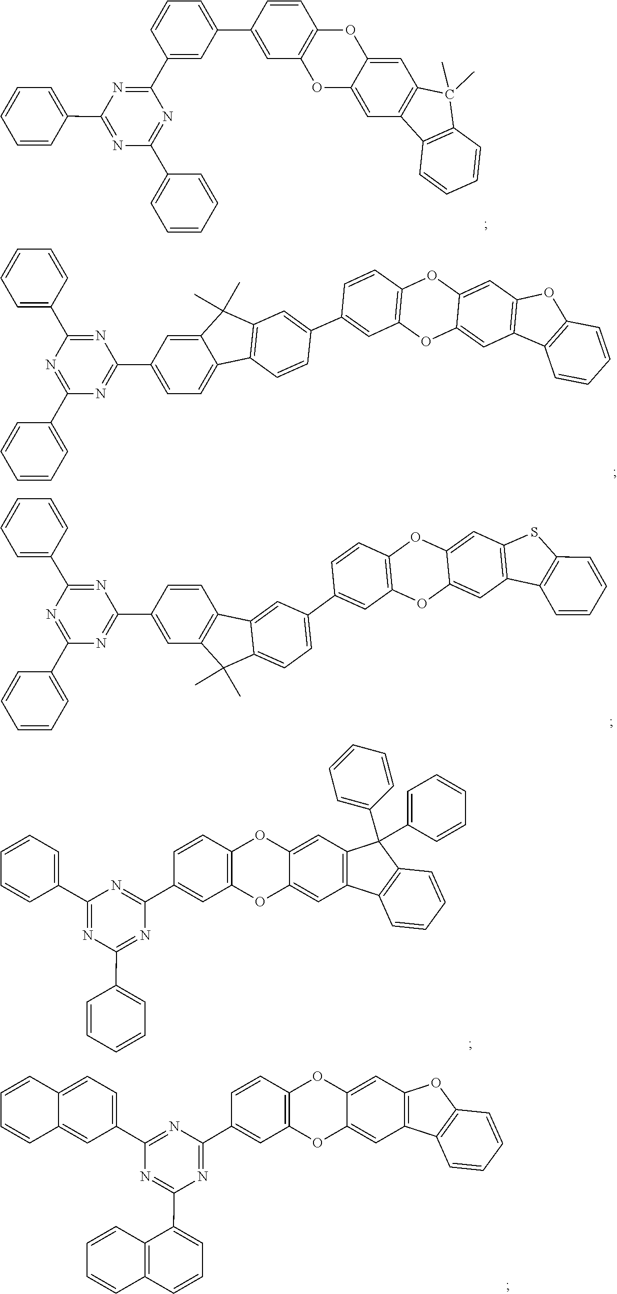

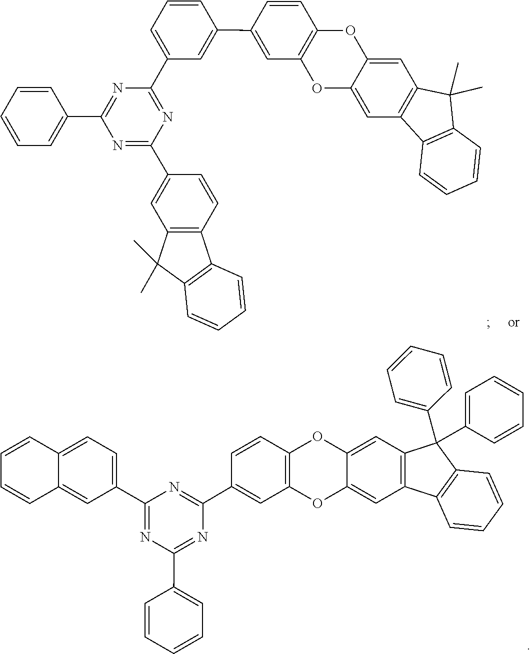 [SMILES: CC1(C)c2ccccc2-c2ccc(-c3nc(-c4ccccc4)nc(-c4cccc(-c5ccc6c(c5)Oc5cc7c(cc5O6)C(C)(C)c5ccccc5-7)c4)n3)cc21 ; c1ccc(-c2nc(-c3ccc4c(c3)Oc3cc5c(cc3O4)C(c3ccccc3)(c3ccccc3)c3ccccc3-5)nc(-c3ccc4ccccc4c3)n2)cc1]

12. The OLED device according to claim 1, wherein the electron mobility of the first electron transport body is 10⁻⁶ cm²V⁻¹s⁻¹-10⁻⁹ cm²V⁻¹s⁻¹.

13. The OLED device according to claim 1, wherein
a band gap width Eg1 of the first electron transport body satisfies a relation:
2.5 eV≤Eg1≤3.6 eV;
and
a band gap width Eg2 of the second electron transport body satisfies a relation:
2.5 eV≤Eg2≤3.6 eV.

14. The OLED device according to claim 1, wherein
a Lowest Unoccupied Molecular Orbital (LUMO) energy level LUMO1 of the first electron transport body and a LUMO energy level LUMO2 of the second electron transport body satisfy a following relation:
0.1 eV≤|LUMO2−LUMO1|≤0.5 Ev;
a Highest Occupied Molecular Orbital (HOMO) energy level HOMO1, and the LUMO energy level LUMO1 of the first electron transport body satisfy a following relation:
HOMO1>5.8 eV, and LUMO1>2.5 eV;
and
a HOMO energy level HOMO2, and the LUMO energy level LUMO2 of the second electron transport body satisfy a following relation:
HOMO2>5.6 eV, and LUMO2>2.5 eV.

15. (canceled)

16. The OLED device according to claim 1, wherein a mass mixing ratio of the first electron transport body to the second electron transport body is 1:100 to 100:1.

17. The OLED device according to claim 1, wherein a difference between an evaporation temperature of the first electron transport body and an evaporation temperature of the second electron transport body is less than 30° C.

18. The OLED device according to claim 1, further comprising:
an electron blocking layer between the anode and the light-emitting layer; and
a hole blocking layer between the light-emitting layer and the electron transport layer;
wherein
a triplet-state energy level of a light-emitting host in the light-emitting layer is smaller than a triplet-state energy level of the electron blocking layer; and
a triplet-state energy level of the hole blocking layer is greater than the triplet-state energy level of the light-emitting host in the light-emitting layer.

19. The OLED device according to claim 18, further comprising:
a hole transport layer between the anode and the electron blocking layer;
wherein
the triplet-state energy level of the second electron transport body in the electron transport layer is greater than the triplet-state energy level of the hole blocking layer; and
a triplet-state energy level of the hole transport layer is greater than the triplet-state energy level of the electron blocking layer.

20. A manufacturing method for the OLED device according to claim 1, comprising:
forming the anode;
forming the hole transport layer on the side of the anode;
forming the light-emitting layer on the side of the hole transport layer facing away from the anode;
forming the electron transport layer on the side of the light-emitting layer facing away from the hole transport layer; and
forming the cathode on the side of the electron transport layer facing away from the light-emitting layer;
wherein the forming the electron transport layer on the side of the light-emitting layer facing away from the hole transport layer comprises:
separately putting the first electron transport body and the second electron transport body in different evaporation sources for co-evaporation; or
forming a mixture by premixing the first electron transport body with the second electron transport body, and performing evaporation by using an evaporation source.

21. (canceled)

22. A display apparatus, comprising an OLED device, wherein the OLED device comprises:
an anode;
a hole transport layer on a side of the anode;
a light-emitting layer on a side of the hole transport layer facing away from the anode;
an electron transport layer on a side of the light-emitting layer facing away from the hole transport layer; wherein the electron transport layer includes: a first electron transport body and a second electron transport body, wherein the first electron transport body has a spiro structure, the second electron transport body has a continuous π conjugated system formed by fusing a dioxin structure and a benzoheterocyclic structure, an electron mobility of the first electron transport body is less than an electron mobility of the second electron transport body, the electron mobility of the second electron transport body is 10⁻⁵ cm²V⁻¹s⁻¹-10⁻⁸ cm²V⁻¹s⁻¹, a triplet-state energy level of the first electron transport body is greater than a triplet-state energy level of the second electron transport body, and the triplet-state energy level of the first electron transport body is greater than 2.4 eV; and
a cathode on a side of the electron transport layer facing away from the light-emitting layer.
